(19) United States
(12) Patent Application Publication
(10) Pub. No.: US 2021/0233718 A1
(43) Pub. Date: Jul. 29, 2021

(54) ORGANIC/INORGANIC HYBRID PHOTOELECTRIC CONVERSION ELEMENT, SOLAR CELL MODULE USING THE SAME, AND METHOD OF MANUFACTURING ORGANIC/INORGANIC HYBRID PHOTOELECTRIC CONVERSION ELEMENT

(71) Applicant: SHARP KABUSHIKI KAISHA, Sakai City (JP)

(72) Inventors: SHINTARO MIYANISHI, Sakai City (JP); HIROSHI SUGIMURA, Sakai City (JP)

(21) Appl. No.: 17/149,312

(22) Filed: Jan. 14, 2021

(30) Foreign Application Priority Data
Jan. 28, 2020 (JP) 2020-011762

(51) Int. Cl. H01G 9/20; H01G 9/00; H01L 51/42; H01L 51/44; H01L 51/00

(52) U.S. Cl. CPC H01G 9/2009; H01G 9/0036; H01G 9/2031; H01L 51/0084; H01L 51/442; H01L 51/0078; H01L 51/4253

(57) ABSTRACT

In an organic/inorganic hybrid photoelectric conversion element, a photoconductor layer including an organic photoconductor material is formed on a laminated film in which a conductive film having translucency and a first titanium oxide layer/a titanium nitride layer are formed in this order on a substrate.

### BACKGROUND OF THE INVENTION

### Field of the Invention

The present invention relates to an organic/inorganic hybrid photoelectric conversion element, a solar cell module using the organic/inorganic hybrid photoelectric conversion element, and a method of manufacturing the organic/inorganic hybrid photoelectric conversion element.

### Description of the Background Art

Photoelectric conversion elements are widely employed in various types of optical sensors, copying machines, solar cells, and the like. In particular, in terms of high photoelectric conversion efficiency and manufacturing cost, photoelectric conversion elements (for example, photoconductors employed in image forming apparatuses such as copying machines and solar cell modules) in which an organic layer and an inorganic layer are laminated are being actively developed. A photoconductor (organic/inorganic hybrid photoelectric conversion element) obtained by combining an organic photoconductor material such as titanyl phthalocyanine and an inorganic material is known to have a high photoelectric conversion efficiency, and the photoconductor (photoelectric conversion element) is employed in an image forming apparatus (see, for example, Japanese Unexamined Patent Application Publication No. 2008-174677, hereinafter referred to as Patent Document 1). Patent Document 1 discloses a method of manufacturing a Y-type titanyl phthalocyanine crystal.

In recent years, solar cell modules using compounds having an organic/inorganic hybrid perovskite crystal structure attract attention by achieving photoelectric conversion efficiencies comparable to those of inorganic materials (see, for example, International Patent Application No. 2017-104792, hereinafter referred to as Patent Document 2). Patent Document 2 discloses a perovskite solar cell technology using a complex and a perovskite material. Photoelectric conversion elements in which an organic material and an inorganic material are combined can be manufactured by an application process without using a vacuum process, and thus, the manufacturing cost can be significantly reduced. Such photoelectric conversion elements are expected to be applied and developed in various fields as photoelectric conversion elements promising in terms of conversion efficiency and cost.

In the perovskite solar cell technology using a complex and a perovskite material (Patent Document 2) and in the method of manufacturing a Y-type titanyl phthalocyanine crystal (Patent Document 1), a photoconductor material is applied to an aggregated body of inorganic fine particles to form a film of the photoconductor material. The organic/inorganic hybrid photoelectric conversion elements manufactured by these techniques do not include a mechanism for efficiently extracting carriers generated by irradiation with light, and thus, there is a problem in that photoexcited carriers easily recombine and an achievable photoelectric conversion efficiency cannot be realized. In particular, in consideration of suppressing the recombination of photoexcited carriers, an interface between the photoconductor layer including an organic photoconductor material such as a perovskite material or titanyl phthalocyanine (light absorption layer) and the inorganic fine particles is not controlled. Thus, there is a problem in that bonding defects, voids, and the like are recombination centers for photoexcited carriers, and thus, the photoexcited carriers are not efficiently extracted from the photoconductor layer. If photoexcited electrons remain at a surface of titanium oxide, a photocatalytic reaction occurs at a surface interface between the photoconductor layer including an organic photoconductor material such as a perovskite material or titanyl phthalocyanine and a titanium oxide layer, and thus, there is a problem in that photolysis of the organic/inorganic hybrid photoelectric conversion element is accelerated.

The present invention has been made in view of the above problems, and an object of the present invention is to provide an organic/inorganic hybrid photoelectric conversion element capable of realizing higher photoelectric conversion efficiency than in a conventional technology, a solar cell module using the organic/inorganic hybrid photoelectric conversion element, and a method of manufacturing the organic/inorganic hybrid photoelectric conversion element, in which the organic/inorganic hybrid photoelectric conversion element includes a photoconductor layer including an organic photoconductor material.

### SUMMARY OF THE INVENTION

As a result of extensive studies to solve the above problems, the inventors have made the following discovery. That is, the lattice constant of a crystal of a titanium nitride layer and the lattice constant of a crystal of a photoconductor layer including an organic photoconductor material such as a perovskite material or titanyl phthalocyanine match well and it is possible to achieve a good crystal growth and crystallization interface, and thus, an effect of suppressing recombination of photoexcited carriers at the interface can be obtained. From this point of view, in an organic/inorganic hybrid photoelectric conversion element including a photoconductor layer containing an organic photoconductor material, if a titanium nitride layer is formed on the surface of a titanium oxide layer and a photoconductor layer including an organic photoconductor material is formed on the titanium nitride layer, an electron band structure is obtained in which photoexcited electrons easily move from the photoconductor layer to the titanium nitride layer and a conductive film. If the photoconductor layer including the organic photoconductor material on the surface of the titanium nitride layer is formed, carriers formed by irradiating the photoconductor layer with light can be efficiently extracted to an external electrode. Thus, it is possible to provide an organic/inorganic hybrid photoelectric conversion element having low weight and high efficiency.

The present invention is based on these findings and provides an organic/inorganic hybrid photoelectric conversion element, a solar cell module, and a method of manufacturing an organic/inorganic hybrid photoelectric conversion element described below.

### (1) Organic/Inorganic Hybrid Photoelectric Conversion Element

An organic/inorganic hybrid photoelectric conversion element according to the present invention is characterized in that a photoconductor layer including an organic photoconductor material is formed on a laminated film in which a conductive film having translucency, a first titanium oxide layer, and a titanium nitride layer are formed in this order on a substrate.

### (2) Solar Cell Module

A solar cell module according to the present invention is characterized in a solar cell module where the organic/inorganic hybrid photoelectric conversion element according to the present invention is integrated.

### (3) Method of Manufacturing Organic/Inorganic Hybrid Photoelectric Conversion Element

A method of manufacturing an organic/inorganic hybrid photoelectric conversion element according to the present invention is a method of manufacturing an organic/inorganic hybrid photoelectric conversion element for manufacturing the organic/inorganic hybrid photoelectric conversion element according to the present invention, and is characterized in that the method includes forming the conductive film on the substrate, forming the first titanium oxide layer on the conductive film, and forming the titanium nitride layer on the first titanium oxide layer and subsequently growing a crystal of the organic photoconductor material.

According to the present invention, it is possible to realize higher photoelectric conversion efficiency than in a conventional technology.

### BRIEF DESCRIPTION OF THE DRAWINGS

FIG. 1 is a schematic diagram of an organic/inorganic hybrid photoelectric conversion element according to a first embodiment;

FIG. 2 is a schematic diagram illustrating a crystal growth orientation of an organic complex and a perovskite material on a titanium nitride plane in the organic/inorganic hybrid photoelectric conversion element according to the first embodiment;

FIG. 3A is a schematic diagram illustrating a crystal growth orientation of titanyl phthalocyanine (Y-type) on the titanium nitride plane in the organic/inorganic hybrid photoelectric conversion element according to the first embodiment;

FIG. 3B is a schematic diagram illustrating a crystal growth orientation of a Y-type titanyl phthalocyanine crystal from directly above the titanium nitride plane illustrated in FIG. 3A;

FIG. 3C is a schematic diagram illustrating a crystal orientation from a viewpoint from a side indicated by a solid arrow in FIG. 3B;

FIG. 4A is a schematic diagram illustrating a crystal growth orientation of titanyl phthalocyanine (Phase II-type) on the titanium nitride plane in the organic/inorganic hybrid photoelectric conversion element according to the first embodiment;

FIG. 4B is a schematic diagram illustrating a crystal growth orientation of a Phase II-type titanyl phthalocyanine crystal from directly above the titanium nitride plane illustrated in FIG. 4A;

FIG. 5 is a schematic diagram illustrating an energy band of the organic/inorganic hybrid photoelectric conversion element according to the first embodiment;

FIG. 6 is a schematic diagram of an organic/inorganic hybrid photoelectric conversion element according to a second embodiment;

FIG. 7 is a photograph obtained by observing a surface of an organic complex and a perovskite crystal structure grown in a bamboo grass shape;

FIG. 8 is a schematic diagram of an organic/inorganic hybrid photoelectric conversion element according to a third embodiment; and

FIG. 9 is a schematic diagram illustrating an energy band of the organic/inorganic hybrid photoelectric conversion element according to the third embodiment.

### DESCRIPTION OF THE PREFERRED EMBODIMENTS

An example in which an organic/inorganic hybrid photoelectric conversion element 100 according to an embodiment of the present invention is applied to a solar cell module 400 will be described below with reference to the drawings. In the following description, same parts are denoted by the same reference numerals. The names and functions of the same parts are also the same. Therefore, detailed description thereof will not be repeated.

### First Embodiment

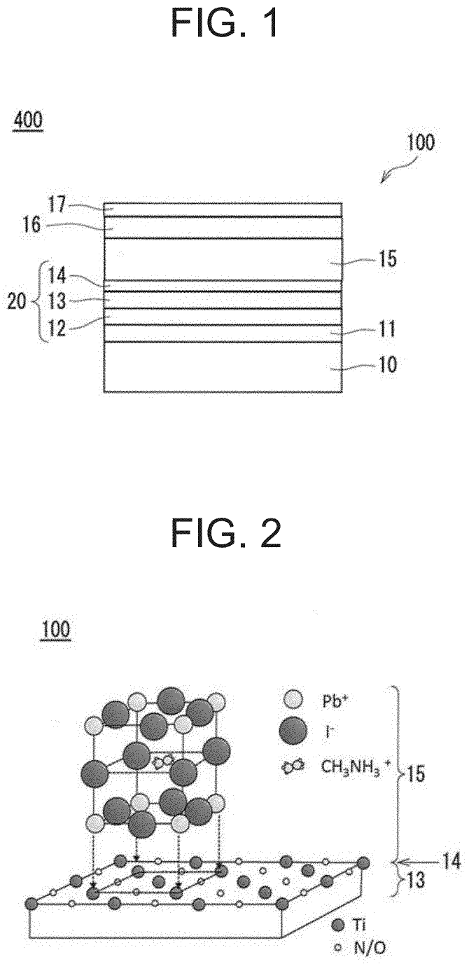

FIG. 1 illustrates a schematic diagram of the organic/inorganic hybrid photoelectric conversion element 100 according to a first embodiment.

As illustrated in FIG. 1, the organic/inorganic hybrid photoelectric conversion element 100 includes a substrate 10, a transparent conductive film layer 11 (an example of a conductive film having translucency), a TiO₂ layer 12 (an example of a first titanium oxide layer), a TiN layer 13 (an example of a titanium nitride layer), an organic/inorganic hybrid photoconductor layer 15 (an example of a photoconductor layer), an electron barrier layer 16 (an example of a layer coated with an inorganic material), and a rear surface electrode layer 17. In this example, a reoxidation layer 14 (an example of a second titanium oxide layer) having a smaller layer thickness than the TiO₂ layer 12 is formed between the TiN layer 13 and the organic/inorganic hybrid photoconductor layer 15. Here, the reoxidation layer 14 is a titanium oxide layer in which the surface of TiN is reoxidized.

That is, the transparent conductive film layer 11 is formed on the substrate 10 of the organic/inorganic hybrid photoelectric conversion element 100. The TiO₂ layer 12 and the TiN layer 13 are formed in this order on the transparent conductive film layer 11 formed on the substrate 10, and in this example, the reoxidation layer 14 is further formed on the TiN layer 13. The organic/inorganic hybrid photoconductor layer 15 including an organic photoconductor material is formed on a surface of a laminated film 20 including the TiO₂ layer 12 and the TiN layer 13 (in this example, the TiO₂ layer 12, the TiN layer 13, and the reoxidation layer 14).

A method of manufacturing the organic/inorganic hybrid photoelectric conversion element 100 includes a first step of forming the transparent conductive film layer 11 on the substrate 10, a second step of forming the TiO₂ layer 12 (the first titanium oxide layer) on the transparent conductive film layer 11, and a third step of forming the TiN layer 13 (the titanium nitride layer) on the TiO₂ layer 12 and subsequently growing a crystal of the organic photoconductor material.

In the third step, the TiN layer 13 (the titanium nitride layer) is formed on the TiO₂ layer 12 (the first titanium oxide layer) and subsequently, the organic photoconductor material is applied to the TiN layer 13 to grow a crystal of the organic photoconductor material.

Substrate 10

Examples of the shape of the substrate 10 include a flat plate shape and a film shape. Examples of the substrate 10 include substrates formed of a material with a high gas barrier property such as a resin plate and a wrap film, and substrates formed of glass. For example, it is desirable that the substrate 10 prevents deterioration inside the organic/inorganic hybrid photoelectric conversion element 100 due to moisture or oxygen in the air and transmits light.

Specific examples of the material forming the substrate 10 include polyethylene terephthalate (PET), polybutylene terephthalate (PBT), polyphenylene sulfide (PPS), polyetherimide (PEI), polytetrafluoroethylene (PTFE), polyamide-imide (PAI), polyethylene naphthalate (PEN), and silicone. However, another resin may be employed as long as the resin fulfills the requirements.

Transparent Conductive Film Layer 11

First, the transparent conductive film layer 11 having a predetermined layer thickness is formed on the substrate 10. In an example, the layer thickness of the transparent conductive film layer 11 may be about 50 nm to 300 nm. The transparent conductive film layer 11 may be formed of, for example, a conductive transparent material such as aluminum-doped zinc oxide (AZO), indium zinc oxide (IZO), gallium-doped zinc oxide (GZO), fluorine-doped tin oxide (FTO), and indium tin oxide (ITO), or alternatively, may be formed by patterning a thin wire of a conductive metal such as silver on an oxide. The characteristics of the transparent conductive film layer 11 desirably has a sheet resistance of 10 Ω/sq or less and a light transmittance of 80% or more. Examples of a method of forming the transparent conductive film layer 11 include sputtering, a vacuum vapor deposition method, a technique for coating/printing a conductive paste, and a low-temperature firing technique.

TiO₂ Layer 12: First Titanium Oxide Layer

Next, the TiO₂ layer 12 having a predetermined layer thickness is formed on the transparent conductive film layer 11. In an example, the layer thickness of the TiO₂ layer 12 may be about 100 nm to 250 nm. Examples of a method of forming the TiO₂ layer 12 include methods similar to the methods of forming the transparent conductive film layer 11. It is desirable that the layer structure of TiO₂ in the TiO₂ layer 12 is a rutile structure.

TiN Layer 13: Titanium Nitride Layer

Next, the TiN layer 13 having a predetermined layer thickness is formed on the TiO₂ layer 12 by a nitriding surface treatment. In an example, the layer thickness of the TiN layer 13 may be about 5 nm to 30 nm. For example, if a surface of the TiO₂ layer 12 is modified by a surface modification process using nitrogen plasma, it is possible to form, on the surface of the TiO₂ layer 12, the TiN layer 13 in which a layer structure of TiN has an NaCl structure. Further, a surface treatment technique using another solution or the like may be employed for forming a TiN metal covering layer. The lattice constants of the crystals in the TiO₂ layer 12 (rutile structure) and the TiN layer 13 (NaCl structure) match relatively well, and thus, it is possible to obtain a good interface having few defects between the TiO₂ layer 12 formed of TiO₂ and the TiN layer 13 formed of TiN. In the vicinity of the interface between the TiO₂ layer 12 and the TiN layer 13, a mixed crystal substance TiO₂₋ₓNₓ is formed. Thus, the lattice constant changes continuously, and the occurrence of an interface defect is suppressed.

Reoxidation Layer 14: Second Titanium Oxide Layer

In this example, the reoxidation layer 14 formed of TiN is formed on the TiN layer 13. For example, if the TiN layer 13 is exposed to the atmosphere after the surface modification process using nitrogen plasma, the reoxidation layer 14 having a thickness of about several nm is formed on a surface of the TiN layer 13. However, in the reoxidation layer 14 that is formed, a TiO₂ film is thin, and thus, the lattice constant does not experience structural relaxation, and the lattice constant of the crystal in the underlying TiN layer 13 is maintained. Here, prior to a step of applying the organic photoconductor material as described later, the surface of the TiN layer 13 may be exposed to the atmosphere or be treated with oxygen plasma. If the reoxidation layer 14 is formed on an interface between the TiN layer 13 and the organic/inorganic hybrid photoconductor layer 15 including the organic photoconductor material, the reoxidation layer 14 being a thin oxide layer having a thickness of about several nm is formed while the lattice constant of the crystal in the TiN layer 13 is maintained, and thus, an effect of suppressing a recombination of carriers at the interface is obtained.

Organic/Inorganic Hybrid Photoconductor Layer 15: Photoconductor Layer

The organic/inorganic hybrid photoconductor layer 15 having a predetermined layer thickness is formed on the TiN layer 13 (the reoxidation layer 14 in this example). For example, if a compound having an organic/inorganic hybrid perovskite crystal structure (hereinafter, simply referred to as a “perovskite structure compound”) serving as an organic photoconductor material is applied to the TiN layer 13 (the reoxidation layer 14 in this example), a crystal of the organic photoconductor material is grown to form the organic/inorganic hybrid photoconductor layer 15.

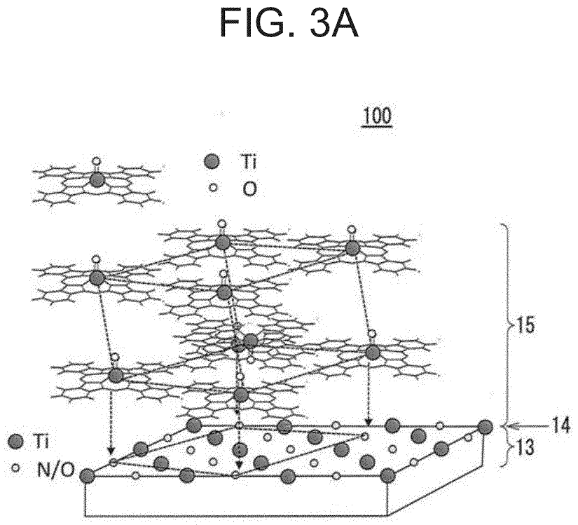

FIG. 2 illustrates a schematic diagram of a crystal growth orientation of an organic complex and a perovskite material on a plane of the reoxidation layer 14 formed of TiN in the organic/inorganic hybrid photoelectric conversion element 100 according to the first embodiment.

As illustrated in FIG. 2, in the organic/inorganic hybrid photoelectric conversion element 100, crystals of the organic complex and/or the perovskite material (in this example, the organic complex and the perovskite material) are grown on the plane of the reoxidation layer 14 formed of TiN to form the organic/inorganic hybrid photoconductor layer 15.

The perovskite structure compound usable in the organic/inorganic hybrid photoconductor layer 15 serving as the primitive unit cell (perovskite crystal structure) of the perovskite structure compound on the plane of the reoxidation layer 14 has a tetragonal primitive unit cell. The unit cell includes an organic group (an organic molecule) A (CH₃NH₃⁺ in the illustrated example) arranged at a body center, a metal atom B (Pb⁺ in the illustrated example) arranged at each vertex, and a halogen atom X (I⁻ in the illustrated example) arranged at each face center, and thus, the unit cell is expressed by the general formula A-B—X₃.

In the general formula A-B—X₃, specific examples of the organic group A (an organic molecule, alkylamine) include methylamine, ethylamine, propylamine, butylamine, pentylamine, hexylamine, dimethylamine, diethylamine, dipropylamine, dibutylamine, dipentylamine, dihexylamine, trimethylamine, triethylamine, tripropylamine, tributylamine, tripentylamine, trihexylamine, ethylmethylamine, methylpropylamine, butylmethylamine, methylpentylamine, hexylmethylamine, ethylpropylamine, ethylbutylamine, imidazole, azole, pyrrole, aziridine, azirine, azetidine, azete, imidazoline, carbazole, and ions of these organic molecules [for example, methylammonium (CH₃NH₃⁺)], or phenethylammonium. These organic groups may be employed alone or two or more of these organic groups may be employed in combination.

Among these organic groups, it is preferable to employ methylamine, ethylamine, propylamine, butylamine, pentylamine, hexylamine, and ions of these organic groups, or phenethylammonium, and particularly preferable to employ methylamine, ethylamine, propylamine, and ions of these organic groups [for example, methylammonium (CH₃NH₃⁺)] for the organic group A.

In the general formula A-B—X₃, specific examples of the metal atom B include lead, tin, zinc, titanium, antimony, bismuth, nickel, iron, cobalt, silver, copper, gallium, germanium, magnesium, calcium, indium, aluminum, manganese, chromium, molybdenum, and europium. These elements may be employed alone or two or more of these elements may be employed in combination. Among these elements, if the metal atom B is lead (Pb), the characteristics of the organic/inorganic hybrid photoconductor layer 15 are even better.

In the general formula A-B—X₃, specific examples of the halogen atom X include chlorine, bromine, and iodine. These elements may be employed alone or two or more of these elements may be employed in combination. Among these elements, at least one of the halogen atoms X is preferably iodine (I) to achieve a narrow energy band gap.

In the organic/inorganic hybrid photoelectric conversion element 100 according to the present embodiment, the perovskite structure compound is preferably a compound expressed by CH₃NH₃PbX₃ (where X is a halogen atom), and the formula CH₃NH₃PbX₃ is more preferably a compound in which X is iodine atom (that is, a compound expressed by CH₃NH₃PbI₃). Thus, in the organic/inorganic hybrid photoconductor layer 15, electrons and holes are generated more efficiently. As a result, the organic/inorganic hybrid photoelectric conversion element 100 having a higher photoelectric conversion efficiency is achieved.

Table 1 shows numerical values of the lattice constants of the crystals of constituent materials forming the organic/inorganic hybrid photoelectric conversion element 100 according to the present embodiment.

TABLE 1

| | | TiO₂ | TiN | Perovskite | TiOPc | TiOPc |
|---|---|---|---|---|---|---|
| | | (rutile | (NaCl | CH₃NH₃PbI₃ | (Y- | (Phase |
| | | structure) | structure) | (tetragonal) | type) | II) |
| Lattice | a | 0.459 nm | 0.423 nm- | 0.88 nm | 1.35 nm | 1.22 mn |
| constant | | | 0.425 nm | | | |
| | b | — | — | — | 1.39 nm | 1.26 nm |
| | c | 0.296 nm | — | 1.27 nm | 1.51 mn | 0.86 nm |

If a perovskite structure compound is formed on the surface of the reoxidation layer 14 having a thickness of several nm (substantially, an NaCl-type TiN tetragonal crystal structure) on the TiN layer 13 (see FIG. 2), the lattice constant of the tetragonal crystal of the perovskite structure compound CH₃NH₃PbI₃ is a=0.88 nm and the lattice constant of the TiN crystal is a=0.423 nm to 0.425 nm (hereinafter, referred to as 0.424 nm) (see Table 1), that is, the lattice constant of the perovskite structure compound CH₃NH₃PbI₃ corresponds to about twice the lattice constant of the TiN crystal (0.424 nm*2=0.848 nm), in the same four-fold rotationally symmetric crystal structure, and thus, crystal lattice mismatch is suppressed to about 3.8% [=|0.88-0.848|/0.848*100] to form a good interface with few defects.

At the interface with few defects between the reoxidation layer 14 and the organic/inorganic hybrid photoconductor layer 15, the probability that electrons and holes generated when light is incident on the organic/inorganic hybrid photoconductor layer 15 are trapped by an interface defect is reduced, and thus, electrons and holes are extracted with high efficiency.

Method of Synthesizing Organic/Inorganic Hybrid Photoconductor Layer 15

The perovskite structure compound usable as the organic/inorganic hybrid photoconductor layer 15 is synthesized by using a compound expressed by AX and a compound expressed by BX₂ as raw materials. Specifically, the perovskite structure compound is synthesized by mixing an AX solution and a BX₂ solution and heating and stirring the resultant solution (one-step method). The perovskite structure compound is also synthesized by applying the BX₂ solution to, for example, the reoxidation layer 14 to form an application film and applying the AX solution to the application film, to react BX₂ and AX (two-step method). Any one of the one-step method and the two-step method may be utilized for forming the organic/inorganic hybrid photoconductor layer 15. Examples of a method of applying the solutions include, but not limited to, a screen printing method, a dip coating method, and an inkjet printing method. The layer thickness of the organic/inorganic hybrid photoconductor layer 15 is preferably in a range of about 500 nm to 1000 nm. Examples of organic solvents include aromatic hydrocarbons such as toluene, xylene, mesitylene, tetralin, diphenylmethane, dimethoxybenzene, and dichlorobenzene; halogenated hydrocarbons such as dichloromethane, dichloroethane, and tetrachloropropane; ethers such as tetrahydrofuran (THF), dioxane, dibenzyl ether, dimethoxymethyl ether, and 1,2-dimethoxyethane; ketones such as methyl ethyl ketone, cyclohexanone, acetophenone, and isophorone; esters such as methyl benzoate, ethyl acetate, and butyl acetate; sulfur-containing solvents such as diphenyl sulfide; fluorine-based solvents such as hexafluoroisopropanol; aprotic polar solvents such as N,N-dimethylformamide, N,N-dimethylacetamide, and dimethyl sulfoxide; alcohols such as methanol, ethanol, and isopropanol; and glyme-based solvents such as ethylene glycol and diethylene glycol monomethyl ether. These solvents may be employed alone or as a mixed solvent. Water may be contaminated in these solvents. Among these solvents, non-halogenated organic solvents may be suitably employed in consideration of the global environment.

In addition to this, additives such as antioxidants, viscoelasticity adjusting agents, preservatives, and curing catalysts may be included.

In the organic/inorganic hybrid photoelectric conversion element 100 according to the present embodiment, titanyl phthalocyanine (TiOPc) (Y-type and Phase II-type) may be employed for the organic/inorganic hybrid photoconductor layer 15.

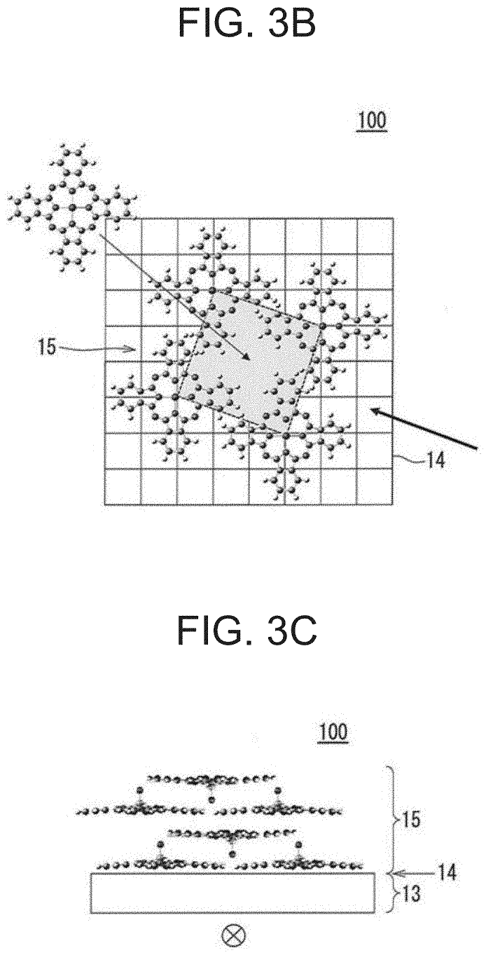

FIG. 3A is a schematic diagram illustrating a crystal growth orientation of titanyl phthalocyanine (Y-type) on the plane of the reoxidation layer 14 formed of TiN in the organic/inorganic hybrid photoelectric conversion element 100 according to the first embodiment. FIG. 3B illustrates a crystal growth orientation of a Y-type titanyl phthalocyanine crystal from directly above the plane of the reoxidation layer 14 illustrated in FIG. 3A, and FIG. 3C illustrates a crystal orientation from a viewpoint from a side indicated by a solid arrow in FIG. 3B.

In the organic/inorganic hybrid photoconductor layer 15, the primitive unit cell of the Y-type titanyl phthalocyanine crystal is approximately tetragonal.

The lattice constant of one side (a=1.35 nm or b=1.39 nm) (see Table 1) of a bottom surface of the approximately tetragonal crystal corresponds to √10 times (10^{1/2} times) the lattice constant of the crystal of the reoxidation layer 14. That is, one side of the approximately tetragonal shape of the Y-type titanyl phthalocyanine crystal is an inclined side of a right angled triangle in which a bottom side of the reoxidation layer 14 is “1” and a side orthogonal to the bottom side is “3” (see FIG. 3B), and thus, the lattice constant of the Y-type titanyl phthalocyanine crystal is √(1²+3²)=√10 and corresponds to √10 times the lattice constant of the crystal of the reoxidation layer 14. The lattice mismatch rate is about 0.7% to 3.7% as described below, and thus, crystal growth starts from a portion where the lattices of the Y-type titanyl phthalocyanine crystal and the reoxidation layer 14 match (in a state where the lattices match). Thus, an interface defect is suppressed.
TiN: 0.424 nm*√10=1.341 and TiOPc: a=1.35, and thus,
   lattice mismatch rate of about 0.7% [=(1.35-1.341)/1.341*100]
TiN: 0.424 nm*√10=1.341 and TiOPc: b=1.39, and thus,
   lattice mismatch rate of about 3.7% [=(1.39-1.341)/1.341*100]

In a method of forming the Y-type titanyl phthalocyanine crystal, O-phthalodinitrile is dispersed in triethylene glycol monomethyl ether, to which titanium tetrabutoxide and O-methylisourea ½ sulfate are added to obtain a solution, and the surface of the reoxidation layer 14 is coated with the solution heated at 145° C. to 155° C., and thus, it is possible to grow the Y-type titanyl phthalocyanine crystal.

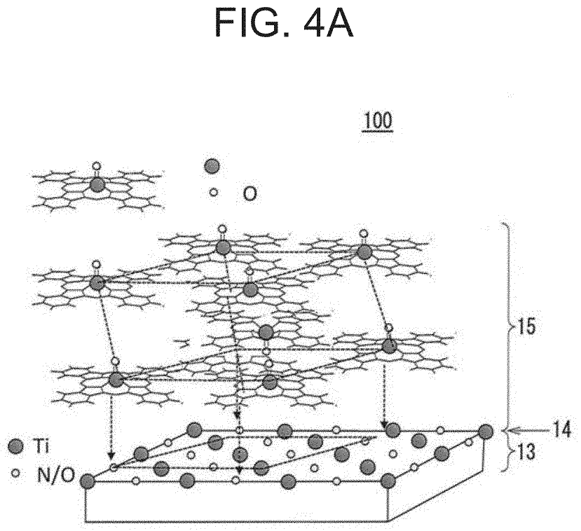

FIG. 4A illustrates a schematic diagram of a crystal growth orientation of a Phase II-type titanyl phthalocyanine crystal on the plane of the reoxidation layer 14 formed of TiN in the organic/inorganic hybrid photoelectric conversion element 100 according to the first embodiment. FIG. 4B illustrates a crystal growth orientation of the Phase II-type titanyl phthalocyanine crystal from directly above the plane of the reoxidation layer 14 illustrated in FIG. 4A.

If the amount of added water is changed in the method of forming the Y-type titanyl phthalocyanine crystal, it is possible to obtain a Phase II-type titanyl phthalocyanine crystal, and the titanyl phthalocyanine crystal is obtained as an orthorhombic crystal by adjusting the difference of the water content. The lattice constant of one side (b=1.26 nm) (see Table 1) of the bottom surface of the orthorhombic crystal corresponds to three times the lattice constant of the crystal of the reoxidation layer 14 (see FIG. 4B). The lattice constant of TiN is 0.424 nm (0.424 nm*3=1.272) and the lattice constant of TiOPc is b=1.26, and thus, the lattice mismatch rate is about 0.9% [=|1.26-1.272|/1.272*100]. As a result, crystal growth starts from a portion where the lattices of TiN and TiOPc match (in a state where the lattices match). Thus, an interface defect is suppressed.

The Y-type titanyl phthalocyanine crystal and the Phase II-type titanyl phthalocyanine crystal described above have a band structure similar to a band structure of the organic/inorganic hybrid photoelectric conversion element 100 in the first embodiment, in terms of an electron structure, and thus, it is possible to realize a photoelectric conversion element having higher efficiency than in the conventional technology.

Electron Barrier Layer 16

The electron barrier layer 16 having a predetermined thickness is formed on the organic/inorganic hybrid photoconductor layer 15. In an example, the thickness of the electron barrier layer 16 may be about 30 nm to 100 nm. The electron barrier layer 16 may be formed as a film of an inorganic material having a band gap of 2 eV or more and an ionization potential of more than −5.3 eV (a shallow ionization potential), for example. Specific examples of the material of the electron barrier layer 16 include oxides and sulfides such as copper oxide (Cu₂O) and zinc sulfide (ZnS).

Rear Surface Electrode Layer 17

The rear surface electrode layer 17 having a predetermined layer thickness is formed on the electron barrier layer 16. For example, a metal film having a high work function (a work function of 5 eV or more) is formed as the rear surface electrode layer 17 on the electron barrier layer 16. If the metal film having a high work function (a work function of 5 eV or more) is formed, a bend in the band structure where holes move smoothly is generated at the interface between the electron barrier layer 16 and the rear surface electrode layer 17. Examples of the material of the rear surface electrode layer 17 include metals such as Ni, Pt, and Pd. The layer thickness of the rear surface electrode layer 17 is desirably about 50 nm to 150 nm, for example. The electron barrier layer 16 and the rear surface electrode layer 17 may be formed by sputtering or a vacuum deposition method, for example.

Energy Band

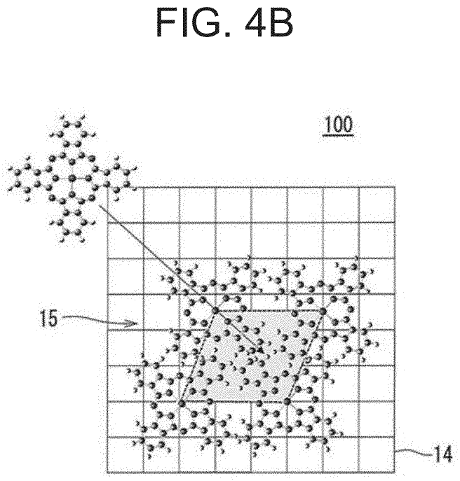

FIG. 5 is a schematic diagram illustrating an energy band of the organic/inorganic hybrid photoelectric conversion element 100 according to the first embodiment. Table 2 shows energy levels of a work function, a band gap (Eg), a conduction band (Ec, LUMO), and a valence band (Ev, HOMO) of each constituent material forming the organic/inorganic hybrid photoelectric conversion element 100 according to the present embodiment. In Table 2, transparent conductive oxide (TCO) represents a material of the transparent conductive film layer 11, TiO₂ represents a material of the TiO₂ layer 12 (the first titanium oxide layer), TiN represents a material of the TiN layer 13 (the titanium nitride layer), Perovskite (CH₃NH₃PbI₃) and TiOPc (Y-type) represent materials of the organic/inorganic hybrid photoconductor layer 15 (an organic/inorganic hybrid photoconductor layer 25 described later), polyvinyl acetal represents a material of a filler 25a described later, Cu₂O and ZnS represent materials of the electron barrier layer 16, and Ni represents a material of the rear surface electrode layer 17, respectively.

TABLE 2

| | Material of | | | Material of | | | | | Material of |
|---|---|---|---|---|---|---|---|---|---|
| | transparent | | | organic/inorganic hybrid | | Material of | | | rear surface |
| | conductive | Material of | Material of | photoconductor layer | | filler | Material of | | electrode |
| | film layer | TiO₂ layer | TiN layer | Perovskite | TiOPc | Polyvinyl | electron barrier layer | | layer |
| | TCO | TiO₂ | TiN | CH₃NH₃PbI₃ | Y-type | acetal | Cu₂O | ZnS | Ni |
| Work | −4.7 | −4.5 | −4.6 | −4.65 | −4.8 | −4.5 | −5 | −5.5 | −5.5 |
| function | | | | | | | | | |
| [eV] | | | | | | | | | |
| Eg | — | 3 | — | 1.5 | 1.6-1.8 | 8.5 | 2.1 | 3.6 | — |
| [eV] | | | | | | | | | |
| Ec, LUMO | — | −4 | — | −3.9 | −3.9 | −1.5 | −3.2 | −1.7 | — |
| [eV] | | | | | | | | | |
| Ev, HOMO | — | −7 | — | −5.4 | −5.7 | −10 | −5.3 | −5.3 | — |
| [eV] | | | | | | | | | |

As illustrated in FIG. 5, an electron e generated in the organic/inorganic hybrid photoconductor layer 15 flows from the reoxidation layer 14 to the transparent conductive film layer 11 via the TiN layer 13 and the TiO₂ layer 12, and thus, the electron e is extracted. The reoxidation layer 14 blocks the flow of a hole h to the transparent conductive film layer 11, and thus, the reoxidation layer 14 has an effect of suppressing a recombination of carriers at the interface between the reoxidation layer 14 and the organic/inorganic hybrid photoconductor layer 15. On the other hand, at the interface between the electron barrier layer 16 and the organic/inorganic hybrid photoconductor layer 15, the hole h generated in the organic/inorganic hybrid photoconductor layer 15 flows to the rear surface electrode layer 17 via the electron barrier layer 16, and thus, the hole h is extracted. As for the electron e, the electron barrier layer 16 blocks the flow of the electron e to the rear surface electrode layer 17, and thus, the electron barrier layer 16 has an effect of suppressing a recombination of carriers at the interface between the electron barrier layer 16 and the organic/inorganic hybrid photoconductor layer 15.

### Second Embodiment

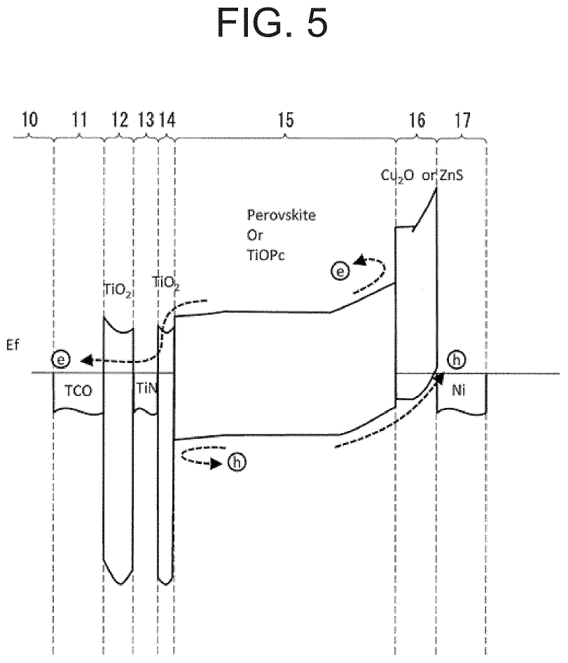

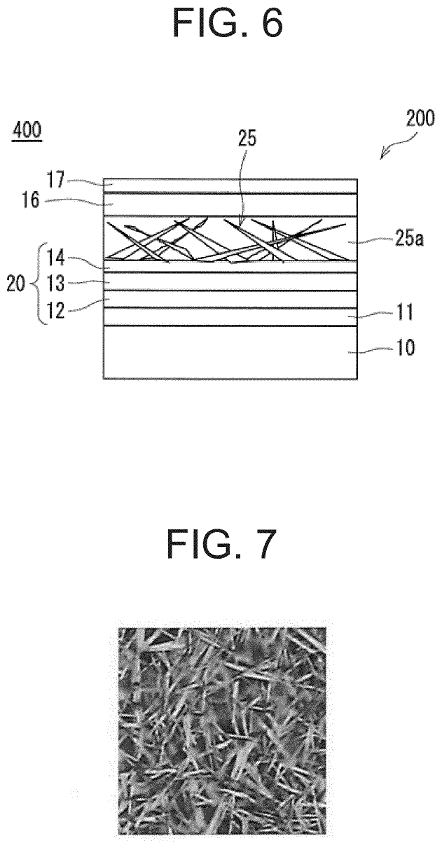

FIG. 6 illustrates a schematic diagram of an organic/inorganic hybrid photoelectric conversion element 200 using an organic complex and/or a perovskite material (in this example, an organic complex and a perovskite material) of which crystals are grown in a bamboo grass shape, as a material of an organic/inorganic hybrid photoconductor layer 25 according to a second embodiment. FIG. 7 is a photograph obtained by observing a surface of an organic complex and a perovskite crystal structure grown in a bamboo grass shape.

Configurations are the same as those in the first embodiment except for the configuration of the organic/inorganic hybrid photoconductor layer 25, and thus, description thereof will be omitted.

As illustrated in FIGS. 6 and 7, in the organic/inorganic hybrid photoelectric conversion element 200, crystals of the organic complex and/or the perovskite material (in this example, the organic complex and the perovskite material) are grow in a bamboo grass shape on the plane of the reoxidation layer 14 formed of TiN.

When a film of the organic complex and the perovskite material is formed as the organic/inorganic hybrid photoconductor layer 25 on the plane of the reoxidation layer 14 formed of TiN, if the temperature of the substrate 10 is low during the forming of the film, a crystal structure having a bamboo grass shape, as illustrated in FIG. 7, is obtained.

Here, an example of a crystal structure having a bamboo grass shape includes a structure in which a large number of bamboo grass-shaped crystals oriented in random directions are densely packed. The bamboo grass-shaped crystals may include rod-shaped crystals, and may include sharpened crystals having a sharp tip end and/or non-sharpened crystals having no sharp tip end, in addition to bamboo grass-shaped crystals having a bamboo leaf shape with a width.

The bamboo grass-shaped crystal desirably has, but not limited to, the length of about 10 μm to 20 μm and the width about 1 μm to 5 μm, and particularly desirably has a bamboo leaf shape. The interface between the plane of the reoxidation layer 14 formed of TiN and the perovskite bamboo grass-shaped crystal includes a good connection interface, and thus, electrons are extracted with high efficiency. An organic binder resin serving as the filler 25a may be applied to a space between the bamboo grass-shaped crystals. A material of the organic binder resin is preferably a non-crystalline material having high insulating properties which needs light-transmissive (in particular, transparent). Specific examples of the organic binder resin include thermoplastic resin such as vinyl resins including polymethyl methacrylate, polystyrene, and polyvinyl chloride, polycarbonate, polyester, polyester carbonate, polysulfone, polyarylate, polyamide, methacrylic resin, acrylic resin, polyether, polyacrylamide, and polyphenylene oxide; and thermosetting resins such as epoxy resin, silicone resin, polyurethane, phenolic resin, alkyd resin, melamine resin, phenoxy resin, and polyvinyl acetal (polyvinyl butyral, polyvinyl formal), and partially crosslinked products of these resins and copolymerized resins including two or more of the structural units included in these resins (insulating resins such as vinylchloride-vinyl acetate copolymer resin, vinyl chloride-vinyl acetate-maleic anhydride copolymer resin, and acrylonitrile-styrene copolymer resin). These film-forming resins may be employed alone or two or more of these resins may be employed in combination. However, another resin may also be employed for the organic binder resin as long as the resin fulfills the requirements. The organic binder resin may include a hole transport material. Pyrazoline compounds, arylamine compounds, stilbene compounds, enamine compounds, polypyrrole compounds, polyvinylcarbazole compounds, polysilane compounds, butadiene compounds, polysiloxane compounds including aromatic amines in a side chain or a main chain, polyaniline compounds, polyphenylene vinylene compounds, polythienylene vinylene compounds, and polythiophene compounds may be employed for the hole transport material. Butadiene compounds and bisbutadiene compounds are particularly preferable as the hole transport material, and further, examples of the hole transport material may include conductive fine particles such as carbon nanofibers and conductive polymers such as poly(3,4-ethylenedioxythiophene)/poly(4-styrenesulfonic acid) (PEDOT/PSS). The hole transport material is preferably a compound that does not easily crystallize. However, an organic binder resin, a plasticizer, or the like may be included to reliably prevent the hole transport material from crystallizing. If an organic solvating media is applied to the bamboo grass-shaped crystal, the organic solvating media is preferably a solvent that does not destroy the crystal structure of the bamboo grass-shaped crystal. Specifically, a solvent such as chlorobenzene or toluene is suitably employed. A method of applying the solvent preferably includes, but not limited to, a dip coating method, a spray coating method, a slide hopper coating method.

If the surface of the bamboo grass-shaped crystal and the exposed surface of the reoxidation layer 14 are coated with the filler 25a mentioned above, current leakage is effectively prevented between the transparent conductive film layer 11 and the rear surface electrode layer 17. The bamboo grass-shaped crystals are solidified by the filler 25a, and thus, the rigidity of the perovskite crystal is improved.

If the bamboo grass-shaped crystals are coated with the filler 25a, light incident on the organic/inorganic hybrid photoconductor layer 25 is multiple-scattered, and thus, the light absorption efficiency in the organic/inorganic hybrid photoconductor layer 25 is improved. Thus, it is possible to increase an amount of extracted carriers (short-circuit current) in the organic/inorganic hybrid photoelectric conversion element 200. As the layer thickness of the organic/inorganic hybrid photoconductor layer 25 is thinner, a higher open circuit voltage is obtained.

### Third Embodiment

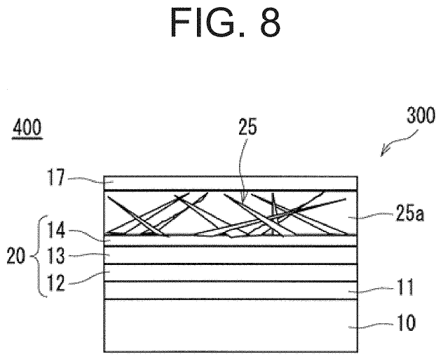

FIG. 8 illustrates a schematic diagram of an organic/inorganic hybrid photoelectric conversion element 300 using an organic complex and a perovskite material grown in a bamboo grass shape, as a material of the organic/inorganic hybrid photoconductor layer 25 according to a third embodiment.

Configurations are the same as those in the second embodiment except for the configuration between the organic/inorganic hybrid photoconductor layer 25 and the rear surface electrode layer 17, and thus, description thereof will be omitted.

In the third embodiment, the rear surface electrode layer 17 is directly formed on the organic/inorganic hybrid photoconductor layer 25 in which the bamboo grass-shaped perovskite crystal is coated with the filler 25a, or alternatively, the rear surface electrode layer 17 is formed after an insulating process for providing an insulating portion having several nm on the surface of the organic/inorganic hybrid photoconductor layer 25. The insulating process includes formation of a film formed of silicon oxide, aluminum oxide, and the like. Examples of main film forming methods include sputtering and a vacuum deposition method.

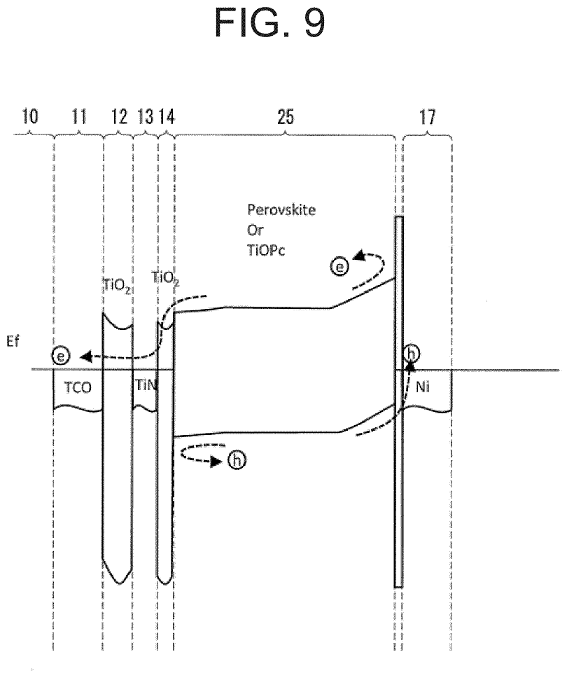

FIG. 9 is a schematic diagram illustrating an energy band of the organic/inorganic hybrid photoelectric conversion element 300 according to the third embodiment.

As illustrated in FIG. 9, at the interface between the organic/inorganic hybrid photoconductor layer 25 and the rear surface electrode layer 17 in the structure illustrated in FIG. 8, the hole h generated by photoexcitation tunnels through an insulator region and flows to the rear surface electrode layer 17. On the other hand, the electron e generated by photoexcitation rebounds on the insulator region, and thus, an effect of suppressing the recombination of carriers at the interface is achieved.

### Fourth Embodiment

The solar cell module 400 is manufactured by integrating the organic/inorganic hybrid photoelectric conversion elements 100, 200, and 300 as described above.

Thus, it is possible to realize the solar cell module 400 in which the organic/inorganic hybrid photoelectric conversion elements 100, 200, and 300 having high efficiency are integrated on a film. Therefore, it is possible to provide the solar cell module 400 having a low weight, a high efficiency, and a large area.

### Present Embodiments

In the first to fourth embodiments described above, the reoxidation layer 14 (the titanium oxide layer in which the surface of TiN is reoxidized) is further arranged on the TiN layer 13 (titanium nitride layer) formed by a nitriding surface treatment on the surface of the TiO₂ layer 12 (the first titanium oxide layer) in this example, and crystals of the organic/inorganic hybrid photoconductor layers 15 and 25 (photoconductor layers) are grown on the reoxidation layer 14, and thus, carriers formed by irradiating the organic/inorganic hybrid photoconductor layers 15 and 25 (photoconductor layers) with light are efficiently extracted to an external electrode. Here, the lattice constant of the crystal of the TiN layer 13 (titanium nitride layer) and the lattice constant of the crystal of the organic/inorganic hybrid photoconductor layer 25 including an organic photoconductor material such as a perovskite material or titanyl phthalocyanine match well, and thus, even if the reoxidation layer 14 (the titanium oxide layer in which the surface of TiN is reoxidized) is formed, it is possible to achieve a good crystal growth and crystallization interface. Thus, an effect of suppressing recombination of photoexcited carriers at the interface is achieved.

If the organic/inorganic hybrid photoconductor layers 15 and 25 (photoconductor layers) are irradiated with light, the photoexcited electrons e conducts from the surface of the reoxidation layer 14 (the second titanium oxide layer) along the TiN layer 13 (titanium nitride layer) and the electrons e efficiently flow from a contacting electrode. Therefore, the photoexcited electrons e are prevented from retaining at the surface interface between the organic/inorganic hybrid photoconductor layer 25 including an organic photoconductor material such as a perovskite material or titanyl phthalocyanine and the reoxidation layer 14 (the second titanium oxide layer) and the photoexcited carriers are prevented from causing a photocatalytic reaction. Thus, it is possible to prevent photolysis of the organic/inorganic hybrid photoconductor layers 15 and 25 (photoconductor layers) to prevent photodegradation of the solar cell module 400.

If the work function and the ionization potential between the inorganic material at the side of the rear surface electrode layer 17 and the electrode are adjusted, the built-in potential is efficiently applied to the organic/inorganic hybrid photoconductor layers 15 and 25 (photoconductor layers) and the holes h (positive holes) of the photoexcited carriers are efficiently extracted at the side of the rear surface electrode layer 17. On the other hand, the rear surface electrode layer 17 serves as a barrier layer for the electrons e, and thus, recombination of photoexcited carriers is suppressed at the side of the rear surface electrode layer 17.

In a laminated film formed by laminating, on the transparent conductive film layer 11 formed on the substrate 10 having a film shape, the TiO₂ layer 12 (the first titanium oxide layer) and the TiN layer 13 (the titanium nitride layer) [in this example, the TiO₂ layer 12, the TiN layer 13, and the reoxidation layer 14 (the second titanium oxide layer)] in this order, it is possible to efficiently extract the electrons e to the side of an electrode, by the organic/inorganic hybrid photoelectric conversion elements 100, 200, and 300 formed by growing a crystal of an organic photoconductor material on the surface of the laminated film. The photoexcited electrons e are prevented from retaining at the surface interface between the organic/inorganic hybrid photoconductor layers 15 and 25 (photoconductor layers) and the reoxidation layer 14 (the second titanium oxide layer), the photoexcited carriers are prevented from causing a photocatalytic reaction, and thus, it is possible to prevent photolysis of the organic photoconductor material to prevent photodegradation of the organic/inorganic hybrid photoelectric conversion elements 100, 200, and 300.

By using the organic/inorganic hybrid photoelectric conversion elements 100, 200, and 300 in which crystals of an organic complex and/or a perovskite material that are grown are employed for the organic photoconductor material, the lattice mismatch between the organic complex and/or the perovskite material and the TiN layer 13 is small, and thus, it is possible to reduce defects at the interface. It is also possible to suppress photodegradation.

By using the organic/inorganic hybrid photoelectric conversion elements 100, 200, and 300 in which a crystal of titanyl phthalocyanine that is grown is employed for the organic photoconductor material, the lattice mismatch between the titanyl phthalocyanine material and the TiN layer 13 is small, and thus, it is possible to reduce defects at the interface. It is also possible to suppress photodegradation.

In the first to fourth embodiments described above, by using the organic/inorganic hybrid photoelectric conversion elements 100, 200, and 300 in which the organic photoconductor material is formed (a crystal of the organic photoconductor material is grown) in a bamboo grass shape and the surfaces of the organic/inorganic hybrid photoconductor layers 15 and 25 (photoconductor layers) are coated with an organic resin material, it is possible to increase a light absorption area. Thus, the light absorption efficiency is increased even with a thin film, and further, the crystal grains obtained by crystal growth are large, and thus, carrier scattering loss due to defects between conduction paths is reduced.

In the first to fourth embodiments described above, by using the organic/inorganic hybrid photoelectric conversion elements 100, 200, and 300 in which the surface of the organic/inorganic hybrid photoconductor layers 15 and 25 is coated with an inorganic material having a band gap of 2 eV or more and an ionization potential of more than −5.3 eV (a shallow ionization potential), if the work function and the ionization potential between the inorganic material at the side of the rear surface electrode layer 17 and the electrode are adjusted, the built-in potential is efficiently applied to the organic/inorganic hybrid photoconductor layers 15 and 25, and thus, the holes h (positive holes) of photoexcited carriers are efficiently extracted at the side of the rear surface electrode layer 17. The layer of the inorganic material serves as a barrier layer for the electrons e, and thus, recombination of photoexcited carriers is suppressed at the side of the rear surface electrode layer 17.

In the first to fourth embodiments described above, by using the organic/inorganic hybrid photoelectric conversion elements 100, 200, and 300 in which a metal film having a work function of 5 eV or more is formed as the rear surface electrode layer 17 on the surface of the organic/inorganic hybrid photoconductor layers 15 and 25, if the work function and the ionization potential between the inorganic material at the side of the rear surface electrode layer 17 and the electrode are adjusted, the built-in potential is efficiently applied to the organic/inorganic hybrid photoconductor layers 15 and 25, and thus, the holes h (positive holes) of photoexcited carriers are efficiently extracted at the side of the rear surface electrode layer 17. On the other hand, the metal film serves as a barrier layer for the electrons e, and thus, recombination of photoexcited carriers is suppressed at the side of the rear surface electrode layer 17.

If the solar cell module 400 in which the above-described organic/inorganic hybrid photoelectric conversion elements 100, 200, and 300 are integrated is employed, it is possible to provide the solar cell module 400 having a film shape, excellent durability, and high efficiency.

In the first to fourth embodiments, the organic/inorganic hybrid photoelectric conversion elements 100, 200, and 300 are applied to the solar cell module 400, but may be applied to other purposes (for example, a photoconductive drum employed in an image forming apparatus such as a copying machine).

Embodiments of the present invention have been described above. However, the present invention is not to be interpreted as being limited to the above-described embodiments and in the implementation of the present invention, constituent components may be modified without departing from the gist of the present invention to embody the present invention. In addition, various configurations may be obtained by appropriately combining the plurality of constituent components disclosed in the embodiments described above.

The present invention relates to an organic/inorganic hybrid photoelectric conversion element including a photoconductor layer containing an organic photoconductor material, and in particular, may be applied for the purpose of realizing higher efficiency in organic/inorganic hybrid photoelectric conversion than in the conventional technology.

What is claimed is:

1. An organic/inorganic hybrid photoelectric conversion element, wherein a photoconductor layer including an organic photoconductor material is formed on a laminated film in which a conductive film having translucency, a first titanium oxide layer, and a titanium nitride layer are formed in this order on a substrate.

2. The organic/inorganic hybrid photoelectric conversion element according to claim 1, wherein
a second titanium oxide layer having a smaller layer thickness than the first titanium oxide layer is formed between the titanium nitride layer and the photoconductor layer.

3. The organic/inorganic hybrid photoelectric conversion element according to claim 1, wherein
the substrate is a film-shaped substrate.

4. The organic/inorganic hybrid photoelectric conversion element according to claim 1, wherein
the organic photoconductor material is a perovskite material.

5. The organic/inorganic hybrid photoelectric conversion element according to claim 1, wherein
the organic photoconductor material is an organic complex.

6. The organic/inorganic hybrid photoelectric conversion element according to claim 1, wherein
the organic photoconductor material is titanyl phthalocyanine.

7. The organic/inorganic hybrid photoelectric conversion element according to claim 1, wherein
the organic photoconductor material is formed in a bamboo grass shape, and
a surface of the photoconductor layer is coated with an organic resin material.

8. The organic/inorganic hybrid photoelectric conversion element according to claim 1, wherein
the surface of the photoconductor layer is coated with an inorganic material having a band gap of 2 eV or more and an ionization potential of more than −5.3 eV.

9. The organic/inorganic hybrid photoelectric conversion element according to claim 1, wherein
a rear surface electrode layer is formed above the photoconductor layer, and
a metal film having a work function of 5 eV or more is formed as the rear surface electrode layer.

10. A solar cell module where the organic/inorganic hybrid photoelectric conversion element according to claim 1 is integrated.

11. A method of manufacturing an organic/inorganic hybrid photoelectric conversion element for manufacturing the organic/inorganic hybrid photoelectric conversion element according to claim 1, the method comprising:
forming the conductive film on the substrate;
forming the first titanium oxide layer on the conductive film; and
forming the titanium nitride layer on the first titanium oxide layer and subsequently growing a crystal of the organic photoconductor material.

12. The method of manufacturing an organic/inorganic hybrid photoelectric conversion element according to claim 11, wherein
in the forming and growing, after the titanium nitride layer is formed on the first titanium oxide layer, the organic photoconductor material is applied to the titanium nitride layer to grow the crystal of the organic photoconductor material.
